(19) United States
(12) Patent Application Publication
(10) Pub. No.: US 2013/0037111 A1
(43) Pub. Date: Feb. 14, 2013

(54) Process for Preparation of Elemental Chalcogen Solutions and Method of Employing Said Solutions in Preparation of Kesterite Films

(71) Applicants: David Brian Mitzi, Mahopac, NY (US); Xiaofeng Qiu, Sleepy Hollow, NY (US)

(72) Inventors: David Brian Mitzi, Mahopac, NY (US); Xiaofeng Qiu, Sleepy Hollow, NY (US)

(73) Assignee: International Business Machines Corporation, Armonk, NY (US)

(21) Appl. No.: 13/207,248

(22) Filed: Aug. 10, 2011

(51) Int. Cl. H01L 31/032; C09K 3/00; H01L 31/18; C09D 11/00; B82Y 30/00

(52) U.S. Cl. 136/264; 438/95; 106/31.13; 252/182.32; 257/E31.027; 977/773

(57) ABSTRACT

Techniques for preparing chalcogen-containing solutions using an environmentally benign borane-based reducing agent and solvents under ambient conditions, as well as application of these solutions in a liquid-based method for deposition of inorganic films having copper (Cu), zinc (Zn), tin (Sn), and at least one of sulfur (S) and selenium (Se) are provided. In one aspect, a method for preparing a chalcogen-containing solution is provided. The method includes the following steps. At least one chalcogen element, a reducing agent and a liquid medium are contacted under conditions sufficient to produce a homogenous solution. The reducing agent (i) contains both boron and hydrogen, (ii) is substantially carbon free and (iii) is substantially metal free.

### FIELD OF THE INVENTION

The present invention relates to techniques for preparing chalcogen-containing solutions using an environmentally benign borane-based reducing agent and solvents under ambient conditions, as well as application of these solutions in a liquid-based method for deposition of inorganic films having copper (Cu), zinc (Zn), tin (Sn), and at least one of sulfur (S) and selenium (Se) and more particularly, to techniques for deposition of kesterite-type Cu—Zn—Sn—(Se,S) materials and improved photovoltaic devices based on these films.

### BACKGROUND OF THE INVENTION

Thin-film chalcogenide-based solar cells provide a promising pathway to cost parity between photovoltaic and conventional energy sources. However, in order to keep production costs down for thin-film chalcogenide-based solar cell production and thus make this technology a viable alternative for conventional energy sources, the ability to deposit the chalcogenide-based absorber layers for the solar cells using liquid-based approaches is important.

A liquid-based approach exists which enables the deposition of kesterite Cu—Zn—Sn—S—Se absorber layer films. This liquid-based approach employs Zn-based nanoparticles and a hydrazine-based solution that contains Cu, Sn, and at least one of S and Se. See, for example, U.S. Patent Application Publication No. 2011/0094557 A1 filed by Mitzi et al., entitled “Method of Forming Semiconductor Film and Photovoltaic Device Including the Film,” (hereinafter “U.S. Patent Application Publication No. 2011/0094557 A1”), U.S. Patent Application Publication No. 2011/0097496 A1, filed by Mitzi et al., entitled “Aqueous-Based Method of Forming Semiconductor Film and Photovoltaic Device Including the Film” (hereinafter “U.S. Patent Application Publication No. 2011/0097496 A1”) and T. Todorov, K. Reuter, D. B. Mitzi, “High-Efficiency Solar Cell With Earth-Abundant Liquid-Processed Absorber,” Adv. Mater. 22, E156-E159 (2010). With this approach, thin-film solar cells with over 10% efficiency have been achieved, which are performance metrics that have not yet been met using vacuum-based or any other processing techniques.

An analogous approach has been described for the preparation of high mobility metal chalcogenide films for thin-film transistor applications, which employs completely dissolved metal chalcogenides with excess chalcogen included in the solution. See, for example, U.S. Pat. No. 6,875,661B2 issued to D. Mitzi, entitled “Solution Deposition of Chalcogenide Films” (hereinafter “U.S. Pat. No. 6,875,661B2”). In each of the above liquid-based techniques, the ability to incorporate an excess amount of at least one of S and Se into the liquid is an important component of the process, since S and Se are volatile elements that may dissociate from the films during thermal processing and since the excess chalcogens may help with film formation and the growth of the grains during the thermal processing.

To date, colloidal and pure-solution chalcogen-containing liquids have been prepared directly from elemental chalcogen by using hydrazine. See, for example, U.S. Pat. No. 4,122,030 issued to Smith et al., entitled “Formation of Colloidal Dispersions of Selenium by the Locus Control Method,” U.S. Pat. No. 6,379,585 B1 issued to Vecht et al., entitled “Preparation of Sulphides and Selenides,” U.S. Pat. No. 7,094,651B2, issued to Mitzi et al., entitled “Hydrazine-Free Solution Deposition of Chalcogenide Films,” U.S. Patent Application Publication No. 2009/0145482 A1, filed by Mitzi et al., entitled “Photovoltaic Device with Solution-Processed Chalcogenide Absorber Layer” and U.S. Pat. No. 6,875,661B2. Colloidal and pure-solution elemental chalcogen liquids have also been prepared directly from elemental chalcogen by using organic ligands, such as trioctylphosphine oxide (TOPO), oleylamine and oleic acid. See, for example, C. B. Murray, D. J. Norris, and M. G. Bawendi, “Synthesis and Characterization of Nearly Monodisperse CdE (E=S, Se, Te) Semiconductor Nanocrystallites,” J. Am. Chem. Soc., 115, 8706-8715 (1993), M. V. Kovalenko, M. Scheele, D. V. Talapin, “Colloidal Nanocrystals with Molecular Metal Chalcogenide Surface Ligands,” Science, 324, 1417-1420 (2009) and Q. Guo, G. M. Ford, W. Yang, B. C. Walker, E. A. Stach, H. W. Hillhouse, R. Agrawal, “Fabrication of 7.2% Efficient CZTSSe Solar Cells Using CZTS Nanocrystals,” J. Am. Chem. Soc., 132, 17384-17386 (2010).

However, hydrazine is an explosive and highly toxic solvent, which must be used under carefully controlled conditions (generally in an inert atmosphere such as nitrogen or argon). Organic ligand molecules may also be toxic and difficult to remove from the resulting film, which may cause a problem in applications such as thin-film electronics (e.g., impurities in the final film).

An organoselenium approach introduces elemental selenium through complicated and toxic organic chemical methodologies. In addition, the costs of such reagents are quite high, which prevents their further application in large scale manufacturing. See, for example, D. Liotta, “New Organoselenium Methodology,” Acc. Chem. Res., 17, 28-34 (1984) and A. J. Mukherjee, S. S. Zade, H. B. Singh, R. B. Sunoj, “Organoselenium Chemistry: Role of Intramolecular Interactions,” Chem. Rev., 110, 4357-4416 (2010).

Other approaches use Se/NaBH₄ or Se/Na₂S to obtain a chalcogen solution. See, for example, D. L. Klayman, T. S. Griffin, “Reaction of Selenium with Sodium Borohydride in Protic Solvents. A Facile Method for the Introduction of Selenium into Organic Molecules” J. Am. Chem. Soc., 95, 197-199 (1973) (hereinafter “Klayman”) (uses Se/NaBH₄) and E. D. Kolb, R. A. Laudise, “The Solubility of Trigonal Se in Na₂S Solutions and the Hydrothermal Growth of Se,” J. Crystal Growth, 8, 191-196 (1971) (uses Se/Na₂S). These processes, however, introduce metal (i.e., Na) impurities that may cause problems for electronics fabrications. Additionally, due to the inorganic nature of sodium borohydride (NaBH₄), it is not easy to dissolve NaBH₄ into some solvents. For example, NaBH₄ is insoluble in ethers and tetrahydrofuran. Also due to the strong reactivity of borohydride (BH₄), in cases involving solvents such as water and methanol, NaBH₄ will adversely react with the solvent.

In U.S. Pat. No. 5,294,370 issued to Wichers et al., entitled “Selenium or Tellurium Elemental Hydrosols and Their Preparation” a Se aqueous solution is prepared by using pyridine borane, however only at low concentration (i.e., less than 0.002M was demonstrated) and starting from SeO₂, which is extremely toxic and introduces oxygen impurity into the solution.

Therefore, the ability to dissolve elemental chalcogens into a wide range of environmentally benign and easy to remove solvents, with significant concentration (e.g., greater than 0.1M), under ambient conditions and without introduction of undesirable and difficult to remove impurities (e.g., Na), is of great importance to the application of chalcogenides in industry. In particular, it is important for the preparation of metal chalcogenide nanoparticles and deposition of metal chalcogenide films for applications ranging from photovoltaics, phase change memory and thin film transistors. Despite the importance of chalcogen solutions, there are few options that can satisfactorily meet these requirements.

Thus, improved techniques for preparing chalcogen-containing solutions and uses thereof would be desirable.

### SUMMARY OF THE INVENTION

The present invention provides techniques for preparing chalcogen-containing solutions using an environmentally benign borane-based reducing agent and solvents under ambient conditions, as well as application of these solutions in a liquid-based method for deposition of inorganic films having copper (Cu), zinc (Zn), tin (Sn), and at least one of sulfur (S) and selenium (Se).

In one aspect of the invention, a method for preparing a chalcogen-containing solution is provided. The method includes the following steps. At least one chalcogen element, a reducing agent and a liquid medium are contacted under conditions sufficient to produce a homogenous solution. The reducing agent (i) contains both boron and hydrogen, (ii) is substantially carbon free and (iii) is substantially metal free.

In another aspect of the invention, a method of preparing a kesterite film on a substrate is provided. The method includes the following steps. A chalcogen-containing solution is prepared as provided above. At least one metal source is contacted with the chalcogen-containing solution under conditions sufficient to produce metal-chalcogenide nanoparticles containing Cu, Sn, Zn and at least one of S and Se. The metal-chalcogenide nanoparticles are isolated. The metal-chalcogenide nanoparticles are dispersed in a liquid medium to form an ink. The ink is deposited on the substrate to form a metal-chalcogenide precursor layer on the substrate. The metal-chalcogenide precursor layer is heat treated to form the kesterite film on the substrate.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for fabricating a kesterite film on a substrate according to an embodiment of the present invention;

FIG. 2 is a cross-sectional diagram illustrating a starting structure for fabricating a photovoltaic device, e.g., a substrate formed from a conductive material or a substrate coated with a layer of conductive material according to an embodiment of the present invention;

FIG. 3 is a cross-sectional diagram illustrating a kesterite film absorber layer having been formed on the substrate according to an embodiment of the present invention;

FIG. 4 is a cross-sectional diagram illustrating an n-type semiconducting layer having been formed on the kesterite film and a top electrode having been formed on the n-type semiconducting layer according to an embodiment of the present invention;

FIG. 5 is a table summarizing results of solvents used for dissolving selenium powder according to an embodiment of the present invention;

FIG. 6 is a scanning electron micrograph (SEM) image of a layer of nanoparticles deposited using the present techniques on a Mo-coated substrate according to an embodiment of the present invention;

FIG. 7 is a diagram illustrating an X-ray diffraction pattern of a Cu₂ZnSn(S,Se)₄ film prepared using the present techniques according to an embodiment of the present invention;

FIG. 8 is a cross-section SEM image of a photovoltaic device prepared by the present techniques according to an embodiment of the present invention; and

FIG. 9 is a graph illustrating photovoltaic performance of a photovoltaic device fabricated according to the present techniques according to an embodiment of the present invention.

### DETAILED DESCRIPTION OF PREFERRED EMBODIMENTS

Provided herein are techniques for preparing chalcogen-containing solutions using an environmentally benign borane-based reducing agent and solvents under ambient conditions, application of these solutions in a liquid-based method for deposition of inorganic films having Cu, Zn, Sn, and at least one of S and Se, and techniques for deposition of kesterite-type Cu—Zn—Sn—(Se,S) materials and improved photovoltaic devices based on these films.

The term “chalcogens,” as used herein, refers to chemical elements from the group 16 column of the periodic table, most notably sulfur (S), selenium (Se) and tellurium (Te). According to the present techniques, the chalcogen sources employed are preferably elemental chalcogens which do not contain unwanted impurities, such as carbon, oxygen and halogens. The morphology of elemental chalcogens can be, but is not limited to, amorphous powder, pellets, flakes and beads.

The term “chalcogenides,” as used herein, refers to compounds that contain chalcogens. According to the present techniques, the chalcogenides employed are preferably metal-containing compounds that contain chalcogens (also referred to herein as “metal chalcogenides”). Examples of metal chalcogenides include, but are not limited to, SnS, SnS₂, SnSe, SnSe₂, SnTe, CuS, CuSe, Cu₂S, Cu₂Se, Cu₂Te, ZnS, ZnSe, ZnTe, In₂S₃, In₂Se₃, In₂Te₃, CuInS₂, CuInSe₂, CuIn(S,Se)₂, Cu₂ZnSnS₄, Cu₂ZnSnSe₄, Cu₂ZnSn(S,Se)₄.

The details provided herein are non-limiting and for exemplary purpose only, demonstrating various modes of applying the present techniques. When components of the present techniques are defined as containing elements, it is to be understood that these elements can be present in either isolated or in compound form, (e.g., a Zn-containing component may contain Zn, ZnS, ZnSe or any other known Zn compound).

It has been found that the ability to prepare elemental chalcogen solutions (i.e., chalcogens fully dissolved in a solvent) is crucial to the preparation of high quality chalcogenide nanocrystals and thin film devices, including solar cells, thin-film transistors and memory devices. Thus, in one aspect, the present invention provides a method to prepare a chalcogen-containing solution. According to an exemplary embodiment, the solution is prepared by contacting (i.e., mixing) at least one chalcogen element, a substantially carbon-free and substantially metal-free boron- and hydrogen-containing reducing agent and a liquid medium under conditions sufficient to produce a homogenous solution.

As highlighted above, the chalcogen element(s) used herein can be any chemical elements from the group 16 column of the periodic table. However, S, Se and Te are preferable for use in accordance with the present techniques.

The term “reducing agent,” as used herein, refers generally to any element or compound that is able to offer electrons to other species in a reduction-oxidation (redox) reaction. In particular, the reducing agents being employed herein are substantially carbon-free, substantially metal-free and contain both boron and hydrogen. The term “substantially carbon-free,” as used herein, refers to compounds of which carbon is not a major element. By way of example only, compounds having a carbon concentration of less than about 2 atomic percent (%), e.g., less than about 0.5 atomic % are considered herein to be “substantially carbon-free” compounds. Using a carbon-free reducing agent is beneficial because carbon impurities can negatively affect semiconductor film formation and device performance. For example, surface-attached carbon species can lead to small grain size of semiconductor materials, which will significantly affect the mobility of charges, therefore, affecting the performance of the electronic devices.

The term “substantially metal-free,” as used herein, refers to compounds in which a level of metal elements or metal ions is below those levels commonly found as impurities in reagent-grade chemicals. By way of example only, compounds having a metal(s) present below 100 parts per million (ppm), e.g., less than about 10 ppm level, are considered herein to be “substantially metal-free” compounds. Use of a metal-free reducing agent is beneficial since, as described above, metal impurities can be problematic for electronics fabrications.

According to the present techniques, suitable reducing agents include compounds containing both boron and hydrogen, such as compounds containing the functional groups of borane (BH₃) or borohydride (BH₄), that give sufficient reducing power to reduce the chalcogens. The reducing agents should therefore have a redox potential more negative than the redox potentials of the elemental chalcogens in the solution. Suitable carbon-free and metal-free boron- and hydrogen-containing reducing agents include, but are not limited to, ammonia borane, ammonia borohydride (BH₄NH₄) and diammoniate of diborane ((NH₃)₂[BH₂]⁺[BH₄]⁻). Preferably, ammonia borane is the reducing agent. Ammonia borane is non-hazardous, contains no metal, dissolves in a wide variety of solvents, is potentially easy to be removed during a thermal processing step and is a strong reducing agent.

In basic solutions ammonia borane can react as in the following reaction:

NH₃BH₃+6OH⁻→BO²⁻+NH₄⁺+4H₂O+6e⁻E₀=−1.216 V.

Basic solutions may be formed, for example, by adding ammonium hydroxide to the solution. Meanwhile, elemental chalcogen can be easily reduced into chalcogen ions as follows:

Te+H⁺+2e⁻=HTe⁻ E₀=−0.817 V

Se+2e⁻=Se²⁻ E₀=−0.67 V

S+2e⁻=S²⁻ E₀=−0.407 V

Therefore, it is very easy for ammonia borane to reduce elemental chalcogen into chalcogen ions, which are easily soluble in many solvents.

The liquid medium is preferably a solvent consisting of water or a non-aqueous liquid, the latter being either an organic or inorganic liquid. Preferably, the liquid medium is a solvent that can be substantially eliminated (e.g., greater than 90% of the solvent can be removed) by evaporation at a temperature lower than the decomposition temperature for the solvent. In one specific embodiment, the liquid medium or solvent, e.g., water, is nonhazardous and preferably but not necessarily excludes the carbon element. Other suitable liquid media include but are not limited to, ammonium hydroxide, water-ammonium hydroxide mixtures, alcohols, ethers, glycols, aldehydes, ketones, alkanes, amines, dimethylsulfoxide (DMSO), cyclic compounds and halogenated organic compounds.

In one exemplary embodiment, the liquid medium dissolves a substantial amount of the reducing agent, for example an amount of the reducing agent of from about 1 micromolar (μM) to 100 molar (M), e.g., from about 1 millimolar (mM) to 20M. In one exemplary embodiment, a liquid medium is used having an acid dissociation constant (pKa) of from about −14 to about 14, for example, a pKa of from about 5 to about 14, e.g., a pKa of from about 7 to about 14, since it is believed that the reducing power is higher in basic media.

As highlighted above, the elemental chalcogen, reducing agent and liquid medium are mixed under conditions sufficient to produce a homogenous solution. These conditions are now discussed. The preparation or reaction requires sufficient temperature to affect the dissolving process. According to an exemplary embodiment, the reaction temperature is targeted to be from about −50 degrees Celsius (° C.) to about 300° C., e.g., from about 15° C. to about 250° C., which is between the melting point and boiling point of most of the above-described liquid media (i.e., solvents).

The reaction condition is particularly targeted to be carried out without inert gas protection. In other words, the reaction is targeted to be carried out in a chemical hood under relative humidity of from about 0% to about 100%, or preferably from about 10% to about 80% relative humidity. Nevertheless, the above does not exclude the possibility of carrying out the reaction under inert atmosphere conditions, including but not limited to nitrogen, argon or helium atmospheres. Although the use of inert atmosphere conditions can add to the cost of the process and potentially reduce the process throughput, benefits of the use of inert atmosphere conditions include providing oxygen- and moisture-free reaction conditions to prevent unwanted impurities like oxygen and water from incorporating into the final products.

Further, the reaction may need agitation to produce a homogeneous solution. By way of example only, magnetic stirring may be employed with a spin speed of from about 10 revolutions per minute (rpm) to about 3,000 rpm, for example, from about 100 rpm to about 1000 rpm, e.g., from about 300 rpm to about 800 rpm. Sonication, as provided by but not limited to an ultrasonic bath or ultrasonic probe, can also be employed to agitate the solution. According to an exemplary embodiment, the source of ultrasound can be varied from 10 kilohertz (kHz) to 10 megahertz (MHz) and the power of the ultrasound may range, for example, from about 1 milliwatt (mW) to about 100 kilowatts (kW). The agitation duration can vary from about 10 seconds to about 180 minutes.

According to an exemplary embodiment, the elemental chalcogen solution prepared using the above-described technique contains at least 1 μM of S, Se and/or Te (preferably more than about 2 mM of S, Se and/or Te). As will be described in detail below, this elemental chalcogen solution is stable and can be used for the preparation of chalcogenide films as well as in the preparation of chalcogenide nanoparticles. By stable it is meant that the present elemental chalcogen solution remains as a homogenous solution for at least 10 minutes, for example, for more than 1 hour, e.g., for more than 1 day, at ambient pressure and at temperatures of from about 0° C. to about 100° C., for example, at temperatures of from about 10° C. to about 80° C., e.g., at temperatures of from about 15° C. to about 40° C.

As provided above, the elemental chalcogen solution may be used in the preparation of metal chalcogenide nanoparticles. These nanoparticles can subsequently be used in an ink for the fabrication of metal chalcogenide films. The elemental composition of the nanoparticles is application-specific based, for instance, on the desired composition of the final film. Thus, in Section I (immediately below) techniques are described for fabricating metal chalcogenide nanoparticles using the present elemental chalcogen solution. The techniques in Section I are applicable to fabricating any type of metal chalcogenide nanoparticle. Following the general description of the nanoparticle fabrication process in Section I, a specific example is provided in Section II relating to the preparation of inks and kesterite (e.g., CZTS/Se) films using a specific metal chalcogenide nanoparticle (i.e., Cu—Zn—Sn—S—Se) prepared using the techniques described in Section I. Section III provides a photovoltaic device that is prepared using the kesterite films and fabrication techniques of Section II.

Section I. Chalcogenide nanoparticles: Provided herein are techniques for using the present elemental chalcogen solutions (prepared as described above) to synthesize metal chalcogenide nanoparticles. According to an exemplary embodiment, the nanoparticle synthesis is carried out by contacting (i.e., mixing and reacting) one or more metal sources with the above-described elemental chalcogen solution under conditions sufficient to produce metal chalcogenide nanoparticles.

The term “nanoparticles,” as used herein, generally refers to an object having at least one dimension (e.g., width, length, diameter, etc.) in the range of from about 1 nanometer (nm) to about 1,000 nm, for example, from about 1 nm to about 200 nm, e.g., from about 5 nm to about 50 nm. See, for example, P. A. Alivisatos “Semiconductor Clusters, Nanocrystals, and Quantum Dots,” Science, 271, 933-937 (1996), (hereinafter “Alivisatos”), the entire contents of which are incorporated by reference herein, which defines the relationship between size of each dimension and the physical properties of the materials. The shape of the particles can be, but is not limited to, spheres, cubes, rods, flakes and stars the formation and application of which are known in the art. See also, “Nanoscale Science, Engineering and Technology Research Directions,” Report prepared at Oak Ridge National Laboratory (ORNL), for the Office of Basic Energy Sciences, U.S. Department of Energy, D. H. Lowndes, General Editor (accessed Jul. 15, 2011 from http://science.energy.gov/˜/media/bes/pdf/reports/files/nset_rpt.pdf) for a discussion of nanoscale materials and their importance to a wide range of applications.

Suitable metal sources include, but are not limited to, elemental metals, metal alloys, metal salts and metal-containing nanoparticles. Exemplary elemental metals include, but are not limited to, elemental copper (Cu), zinc (Zn), tin (Sn), germanium (Ge), indium (In), iron (Fe) and gallium (Ga). Exemplary metal alloys include, but are not limited to, Cu—Sn, Cu—Zn, Zn—Sn, Cu—Al, Cu-nickel (Ni), Cu—In and In—Ga alloys. Exemplary metal salts include, but are not limited to, metal halides, acetates, nitrates, sulfates, organometallic compounds. Organometallic compounds are chemical compounds containing bonds between carbon and a metal. Examples include copper acetylacetonate, zinc acetylacetonate, tin(II) phthalocyanine and iron pentacarbonyl.

Some exemplary metal halides include, but are not limited to, copper chloride, copper bromide, copper fluoride, copper iodide, zinc chloride, zinc bromide, zinc fluoride, zinc iodide, tin chloride, tin bromide, tin iodide, indium chloride, germanium chloride, gallium chloride, indium fluoride, indium bromide, indium iodide, iron chloride and iron bromide. Some exemplary metal acetates include, but are not limited to, copper acetate, zinc acetate, tin acetate, iron acetate and indium acetate. Some exemplary metal nitrates include, but are not limited to, copper nitrate, zinc nitrate, tin nitrate, iron nitrate and indium nitrate. Some exemplary metal sulfates include, but are not limited to, copper sulfate, zinc sulfate, tin sulfate, iron sulphate and indium sulfate.

Some exemplary metal-containing nanoparticles include, but are not limited to, copper-containing nanoparticle materials such as CuS, Cu₂S, CuSe, Cu₂Se, Cu₂SnS₃, Cu₄SnS₄, Cu₂SnSe₃, Cu₂ZnSnS₄, Cu₂ZnSnSe₄, Cu₂ZnSn(S,Se)₄, CuInS₂, CuInSe₂, CuGaSe₂, Cu(In,Ga)Se₂, Cu(In,Ga)(S,Se)₂, tin-containing nanoparticle materials such as SnS, SnS₂, SnSe, SnSe₂, Cu₂SnS₃, Cu₄SnS₄, Cu₂SnSe₃, Cu₂ZnSnS₄, Cu₂ZnSnSe₄ and Cu₂ZnSn(S,Se)₄, zinc-containing nanoparticle materials such as ZnS, ZnSe, Cu₂ZnSnS₄, Cu₂ZnSnSe₄ and Cu₂ZnSn(S,Se)₄ and iron-containing materials such as FeS and FeS₂.

Optionally, one or more compatible solvents or co-solvents may be added to the elemental chalcogen solution or to the metal sources in order to dissolve the metal sources before reacting them with the elemental chalcogen solution. The solvent or co-solvent can also be useful to adjust the pH of the solution, or to adjust the viscosity of the solution, melting/boiling/flash point of the solution, or the flammability of the solution. Preferably, the optional solvent or co-solvent is non-hazardous and excludes the carbon element. An example of such a solvent is water. As highlighted above, a carbon-free solvent is advantageous to avoid carbon contamination in films prepared using the resulting nanoparticles and dispersions based on the nanoparticle. Alternatively, examples of other solvents and co-solvents that may be used in this step include, but are not limited to, alcohols, ethers, glycols, aldehydes, ketones, alkanes, amines, dimethylsulfoxide (DMSO), cyclic compounds and halogenated organic compounds.

As highlighted above, the metal source(s) are mixed/reacted with the elemental chalcogen solution under conditions sufficient to produce metal chalcogenide nanoparticles. These conditions are now discussed. The reaction between the metal source(s) and the elemental chalcogen in solution to form the metal chalcogenide nanoparticles may take place at a temperature at or above room temperature, for example, at a temperature of from about 20° C. to about 300° C., e.g., from about 30° C. to about 150° C. At these temperatures most of the above-described solvents are in their liquid phase. This reaction may be carried out in a chemical hood under ambient temperature and pressure, in a nitrogen- or argon-filled drybox or in an inert-gas-operated Schlenk line for a duration of from about 1 second to several days under agitation as mentioned above in the description of the preparation of the chalcogen solution. Agitation is necessary to keep the nanoparticles from sticking together, since after the metal chalcogenide nanoparticles are formed in the reaction, the nanoparticles very easily agglomerate (and thereby become not easy to fully disperse).

Under these conditions, metal-chalcogenide nanoparticles will form in the solution. The particles can be prepared by any standard technique known to those skilled in the art, such as, but not limited to, solution-based, e.g., controlled precipitation, sol-gel, wet atomization, gas-phase reactions, sonochemistry, sonoelectrochemistry and electrochemistry. Namely, since there are certain requirements for the dimensional control of the materials, certain chemical reaction conditions or agitation conditions need to be met to facilitate the nanoparticle growth. Mostly, these techniques are used when two or more substances meet each other and one or more chemical reactions or physical mixing must happen (for example, by using certain types of ultrasonication, the reaction product can be quickly dispersed into the liquid medium, therefore preventing the particles from growing bigger than nanometer scale. Or when electrochemistry is involved in the chemical reactions, a high current density will lead to the formation of more nuclear centers, therefore limiting the particle size. Associated with appropriate agitation steps, the growth of the materials can be terminated at the time their dimensions are still in nanometer-scale range).

By way of example only, metal-chalcogenide nanoparticles formed by this process may include binary, ternary, quaternary and multinary (more than four element) materials containing at least one chalcogen element of S, Se or Te. Examples of these materials include, but are not limited to, SnS, SnS₂, SnSe, SnSe₂, SnTe, Cu₂S, Cu₂Se, Cu₂Te, ZnS, ZnSe, ZnTe, In₂S₃, In₂Se₃, In₂Te₃, FeS, FeS₂, CuInS₂, CuInSe₂, CuIn(S,Se)₂, CuGaSe₂, Cu(In,Ga)Se₂, Cu(In,Ga)(S,Se)₂, Cu₂ZnSnS₄, Cu₂ZnSnSe₄, Cu₂ZnSn(S,Se)₄, Cu₂Zn(Sn,Ge)S₄, Cu₂Zn(Sn,Ge)Se₄ and Cu₂Zn(Sn,Ge)(S,Se)₄.

The nanoparticles may be isolated from the solution using centrifugation or filtration and, for example, can be redispersed in a liquid medium (e.g., solvent(s)) that is/are tailored for the film deposition process (e.g., selected to wet the substrate effectively and to not leave impurity contamination). Suitable solvents for film deposition include, but are not limited to, water, water-hydrazine mixtures, ammonium hydroxide, ethylene glycol, 2-methoxyethanol, and dimethyl sulfoxide (DMSO). This process creates a dispersion or ink that may be used for the preparation of films for electronic devices including solar cells.

In one exemplary embodiment, the isolated nanoparticles may be dispersed in clean elemental chalcogen solution to form a dispersion or ink. By way of example only, if the elemental chalcogen solution contains S and/or Se, then redispersing the nanoparticles in the elemental chalcogen solution would be advantageous because excess chalcogen (above the content needed for the final film) can enable control over the final film chalcogen content, due to the volatile nature of these elements during the heating process, and to facilitate grain growth during the heat treatment process.

Of course, the composition of the ink can vary depending on the composition of the elemental chalcogen solution and/or the metal source(s) used in the reaction to form the metal-chalcogenide nanoparticles. For example, as highlighted above, a specific exemplary implementation of the present techniques relates to the preparation of inks and kesterite (e.g., CZTS/Se) films using a specific metal chalcogenide nanoparticle (i.e., Cu—Zn—Sn—S—Se) prepared using the techniques described in Section I. This example is now described.

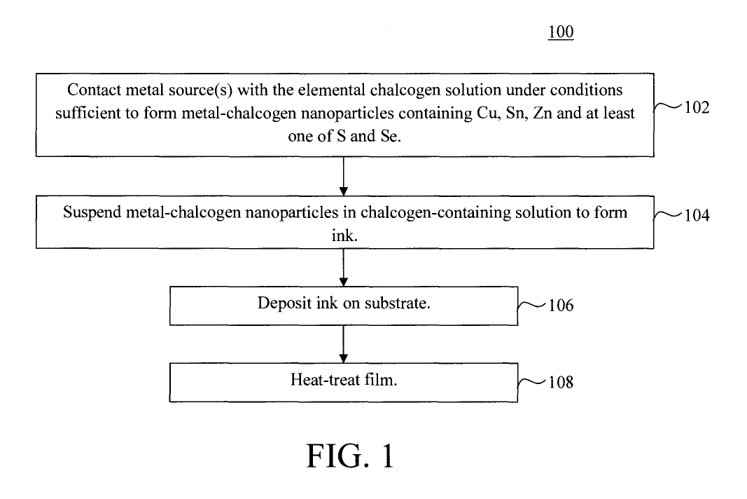

Section II. Metal-chalcogenide nanoparticle-based ink for CZTSSe film fabrication: By way of reference to FIG. 1, in the following embodiment, an exemplary methodology 100 is provided for preparing a metal-chalcogenide nanoparticle-based dispersion or ink for preparing a kesterite film of the formula:

Cu₂₋ₓZn_{1+y}Sn(S_{1-z}Se_{z})_{4+q} or (CZTSSe), (1)

wherein 0≦x≦1; 0≦y≦1; 0≦z≦1; −1≦q≦1. Preferably, the kesterite film has the above Formula I wherein x, y, z and q respectively are: 0≦x≦0.5; 0≦y≦0.5; 0≦z≦1 and −0.5≦q≦0.5.

To begin the process, in step 102, metal chalcogenide nanoparticles are prepared as described in conjunction with the description of Section I, above. As explained above, the process described in Section I is generally applicable to producing metal chalcogenide nanoparticles with a variety of different elemental compositions. In this example, however, the metal chalcogenide nanoparticles being sought are those containing Cu, Zn, Sn and at least one of S and Se. Therefore, some of the exemplary metal sources described in Section I above are not applicable in this example, such as those containing Ge, In, Fe and Ga. Otherwise, the conditions for nanoparticle formation remain the same as those presented in Section I above.

For instance, according to an exemplary embodiment, the (Cu—Zn—Sn—S—Se) metal chalcogenide nanoparticles are prepared by contacting the metal sources (in this case a source of Cu, a source of Sn and a source of Zn) with the elemental chalcogen solution, as per the steps detailed in Section I, above. Suitable (Cu, Sn and Zn) metal sources in this example include, but are not limited to, elemental Cu, elemental Zn, elemental Sn, Cu—Zn alloys, Zn—Sn alloys, Cu—Sn alloys, copper chloride, copper fluoride, copper bromide, copper iodide, zinc bromide, zinc fluoride, zinc chloride, zinc iodide, tin chloride, tin bromide, tin iodide, copper acetate, zinc acetate, tin acetate, copper nitrate, zinc nitrate, tin nitrate, copper sulfate, zinc sulfate, tin sulfate, CuS, Cu₂S, CuSe, Cu₂Se, Cu₂SnS₃, Cu₄SnS₄, Cu₂SnSe₃, ZnS, ZnSe, SnS, SnS₂, SnSe, SnSe₂, Cu₂ZnSnS₄, Cu₂ZnSnSe₄, Cu₂ZnSn(S,Se)₄. It is notable that, by comparison with the metal sources provided in Section I above, these exemplary metal sources do not contain germanium (Ge), indium (In), iron (Fe) and gallium (Ga) since these elements are not desired in the final product.

The (Cu—Zn—Sn—S—Se) metal chalcogenide nanoparticles may be prepared and isolated from the solution using the same techniques described in Section I above. In step 104, the isolated metal chalcogenide nanoparticles may then be used to form an ink. According to an exemplary embodiment, the ink is prepared by dispersing the metal chalcogenide nanoparticles in a suitable liquid medium. According to an exemplary embodiment, the liquid medium is a solvent that is nonhazardous and preferably but not necessarily excludes the carbon element, an example being water. Other examples of solvents include but are not limited to: ammonium hydroxide, water-ammonium hydroxide mixtures, alcohols, ethers, glycols, aldehydes, ketones, alkanes, amines, dimethylsulfoxide (DMSO), cyclic compounds, halogenated organic compounds.

In one exemplary embodiment, the liquid medium used is clean elemental chalcogen solution prepared as described above. In this manner, more S and/or Se (depending on the composition of elemental chalcogen solution) is included in the dispersion than the amount required to satisfy the stoichiometry requirements for the kesterite compound in the starting solution. As mentioned previously, excess chalcogen can enable control over the final film chalcogen content, due to the volatile nature of these elements during the heating process, and facilitate grain growth during the heat treatment process. The elemental chalcogen solution is therefore important for providing the possibility to supply this excess chalcogen, without resorting to highly toxic and explosive reducing agents (e.g., hydrazine) or expensive and difficult-to-remove organo-chalcogen compounds.

Optionally, an additional chalcogen source can be included in the ink, as well as a co-solvent(s). The ratio between the metal amounts included in the ink are defined by x, y, z and q from the kesterite Formula I above. The molar ratio between total ink chalcogen content and total metal content varies, for example, from about 1 to about 100.

The optional additional chalcogen (S or Se) source may be, for example, elemental selenium, elemental sulfur, ammonium sulfide [(NH₄)₂S] and/or ammonium selenide [(NH₄)₂Se]. The additional chalcogen source may either be introduced in dissolved form or nanoparticle form. Exemplary dissolved forms of a chalcogen source include, but are not limited to, an ammonium sulfide solution and an ammonium selenide solution. Exemplary chalcogen source nanoparticles include, but are not limited to, sulfur nanoparticles and selenium nanoparticles. By way of example only, the elemental chalcogen solution may contain S and a source of selenium is added to the solution, or vice versa, to produce nanoparticles containing both S and Se.

In one specific embodiment, the optional co-solvent for nanoparticle dispersion, for example water, is nonhazardous and preferably but not necessarily excludes the carbon element. Other examples of solvents or optional co-solvent include but are not limited to: ammonium hydroxide, water-ammonium hydroxide mixtures, alcohols, ethers, glycols, aldehydes, ketones, alkanes, amines, dimethylsulfoxide (DMSO), cyclic compounds, halogenated organic compounds.

Optionally, a source of one or more of lithium (Li), sodium (Na), potassium (K), magnesium (Mg), calcium (Ca), strontium (Sr), barium (Ba), boron (B), antimony (Sb), bismuth (Bi) and Ge is added to the solution, and thereby these additives become incorporated into the nanoparticles. A small amount (e.g., from about 0.0001 percent by weight (% wt) to about 2% wt) of additives are sometimes added into the ink mixture to improve the film formation or certain physical properties. For example, Na is a well known additive in photovoltaic films that is used to change the conductivity of the material. See, for example, A. Rockett, “The effect of Na in polycrystalline and epitaxial single-crystal CuIn(1−x)Ga(x)Se2,” Thin Solid Films, 480-481, 2 (2005), the entire contents of which are incorporated by reference herein.

The ink can be prepared in a chemical hood under ambient temperature and pressure, in a nitrogen- or argon-filled drybox or in an inert-gas-operated Schlenk line. Further, agitation may be employed to keep the nanoparticles from sticking together as mentioned in Section I above.

According to an exemplary embodiment, a concentration of the metal(s) in the metal-chalcogenide nanoparticle-based ink produced by the above-described process is from about 1 micromolar (μM) to about 5 molar (M), for example, from about 1 millimolar (mM) to about 2M. A concentration of the chalcogen(s) in the ink is from about 1 μM to about 5M, for example, from about 1 mM to about 2M.

In this example, since Cu, Sn and Zn were used in the preparation of the metal-chalcogenide nanoparticles, by way of example only, metal-chalcogenide nanoparticles formed by this process may include binary, ternary, quaternary and/or multinary materials containing Cu, Sn and Zn and at least one chalcogen element of S, Se or Te. Examples of these materials include, but are not limited to, Cu₂ZnSnS₄, Cu₂ZnSnSe₄ and Cu₂ZnSn(S,Se)₄.

According to an exemplary embodiment, it is preferable that a size of the metal-chalcogen nanoparticles in the ink is smaller than a thickness of the kesterite film being deposited. Specifically, the nanoparticle size dictates the minimum film thickness. Thus, if the nanoparticles were larger in size than the film thickness, then even a single layer of particles could not be used to achieve the desired film thickness with good resulting film uniformity and acceptable film roughness. As highlighted above, nanoparticle size may be quantified as at least one dimension (e.g., width, length, diameter, etc.) of the nanoparticle falling within a certain range, for instance in the range of from about 1 nm to about 1,000 nm, for example, from about 1 nm to about 200 nm, e.g., from about 5 nm to about 50 nm. The shape of the particles can be, but is not limited to, spheres, cubes, rods, flakes and stars.

As highlighted above, the metal-chalcogenide nanoparticles optionally contain one or more of Li, Na, K, Mg, Ca, Sr, Ba, B, Sb, Bi and Ge. As described above, adding these elements to the nanoparticles can improve the film formation and/or affect certain physical properties of the film, such as conductivity. An outstanding advantage of the process is the possibility to avoid using highly toxic reactants such as hydrazine, hydrazine monohydrate or selenourea during the preparation of kesterite films. The possibility of using water as a solvent can greatly reduce the toxicity and flammability of the ink. Furthermore, the preparation of the elemental chalcogen solution, the nanoparticles, the ink and possibly the film development can be all carried out without inert gas protection and in a water-free environment, which can greatly reduce the manufacturing cost of the process.

Another advantage of the present invention is to avoid or reduce the necessity of enhancing additives, in particular organic polymers acting as binders, surfactants and/or extenders, as their function can be substantially engineered by adequate introduction of desirable dissolved components that are subsequently incorporated into the final composition. Reducing the number of components reduces production costs and complexity. In some cases, additives can be conveniently eliminated, e.g., by thermal anneal in oxidizing atmosphere when oxide materials are targeted. However, in cases where additive use is desirable the additives can be readily integrated into the process. In such cases, the ink may optionally contain one or more enhancing additives that improve the dispersion of the solid phase and/or the solubility of the liquid phase and/or the rheological properties of the ink. Some non-limiting examples of such additives include: binders, viscosity modifiers, pH modifiers, dispersants, wetting agents and/or solubility enhancers, such as, polymers, surface active compounds, complex forming agents, e.g., amines, and acidic and basic substances.

The ink may then be used to fabricate a kesterite film of the Formula I, given above. Namely, in step 106, the ink is deposited as a metal chalcogenide precursor layer onto a substrate. The term “precursor” refers to the fact that the deposited layer contains the elements needed to form the final film. However, until the layer is annealed (as described below) to enable formation of the kesterite crystal structure, the layer is only a precursor to the final film.

By way of example only, suitable substrates include, but are not limited to, a metal foil substrate, a glass substrate, a ceramic substrate, aluminum foil coated with a (conductive) layer of molybdenum, a polymer substrate, and any combination thereof. It is preferable that the substrate is coated with a conductive coating/layer (such as a molybdenum layer) if the substrate material itself is not inherently conducting. Namely, the present techniques may be employed to form an absorber layer of a photovoltaic device (see below). The conductive coating/layer or substrate can, in that instance, serve as an electrode of the device. In one embodiment the substrate is metal or alloy foil containing as non-limiting examples molybdenum, aluminum, titanium, iron, copper, tungsten, steel or combinations thereof. In another embodiment the metal or alloy foil is coated with an ion diffusion barrier and/or an insulating layer succeeded by a conductive layer. In another embodiment the substrate is polymeric foil with a metallic or other conductive layer, e.g., transparent conductive oxide, carbon) deposited on the top of it. In one preferred embodiment, regardless of the nature of the underlying substrate material or materials, the surface contacting the liquid layer contains molybdenum.

The ink may be deposited on the substrate using spin-coating, dip-coating, doctor blading, curtain coating, slide coating, spraying, slit casting, meniscus coating, screen printing, ink jet printing, pad printing, flexographic printing or gravure printing. After a liquid layer of the ink is deposited on the surface of the substrate, the process of drying the film and removing some part of the excess chalcogen may be initiated by evaporation, by means of exposure to ambient or controlled atmosphere or vacuum that may be accompanied with a thermal treatment, referred to as preliminary anneal, to fabricate a substrate coated with a hybrid precursor including discrete particles and surrounding media. This surrounding media is formed by solidification of the dissolved component.

In step 108, a heat treatment (annealing) of the metal chalcogenide precursor layer is performed. Namely, the metal chalcogenide precursor layer is heated to a temperature sufficient to induce reaction/recrystallization and grain growth among the nanoparticles therein to form a nominally single-phase film with an average grain size with at least one dimension greater than 50 nm, e.g., greater than 200 nm, with the kesterite composition. According to an exemplary embodiment, the heat treatment involves heating the kesterite film to a temperature of from about 200° C. to about 800° C., for example, from about 400° C. to about 600° C., e.g., from about 500° C. to about 600° C., for a duration of from about 1 second to about 120 minutes, e.g., from about 2 minutes to about 30 minutes. The step of heat treating is preferably carried out in an atmosphere including at least one of nitrogen, argon, helium, forming gas, and a mixture containing at least one of the foregoing gases. This atmosphere can further include vapors of at least one of S, Se and a compound containing S and/or Se (e.g., H₂S and H₂Se). The ratio of S and Se sources in the vapor can be selected to impact the final S:Se ratio in the final film. The kesterite film produced in this manner preferably contains at least 80% by mass of the targeted compound, more preferably at least 90% by mass of the targeted compound and even more preferably at least 95% by mass of the targeted compound. The targeted compound is the CZTSSe kesterite compound of the formula provided above.

The preliminary and/or reactive anneal can be carried out by any technique known to one of skill in the art, including but not limited to, furnace, hot plate, infrared or visible radiation and convective (e.g., laser, lamp furnace, rapid thermal anneal unit, resistive heating of the substrate, heated gas stream, flame burner, electric arc and plasma jet). The duration of this anneal can vary depending on the process and typically is from about 0.1 sec. to about 72 hr. The intimate contact between the two components of the hybrid precursor (particle component and solidified dissolved component) for most embodiments enables limiting the anneal duration to less than 60 minutes (as provided above).

Other techniques for fabricating kesterite films are described in U.S. patent application Ser. No. ______, filed herewith on the same day of ______, entitled “Capping Layers for Improved Crystallization,” designated as Attorney Reference Number YOR920110408US1, and in U.S. patent application Ser. No. ______, filed herewith on the same day of ______, entitled “Particle-Based Precursor Formation Method and Photovoltaic Device Thereof,” designated as Attorney Reference Number YOR920110412US1, the entire contents of each of which are incorporated by reference herein.

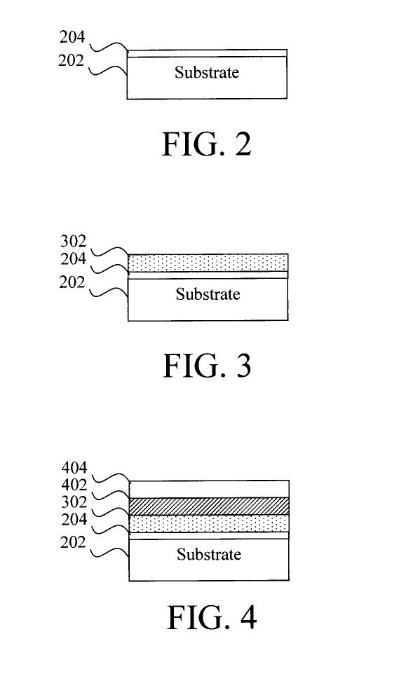

The obtained film on substrate may then be used for the desired application, such as, optical, electrical, anti-friction, bactericidal, catalytic, photo-catalytic, electromagnetic shielding, wear-resistance, and diffusion barrier. In one exemplary embodiment, methodology 100 may be used to form a kesterite film absorber layer for a photovoltaic device. See, for example, FIG. 2-4.

Section III. Photovoltaic device prepared using the kesterite films and fabrication techniques of Section II. To begin the photovoltaic device fabrication process, a substrate 202 is provided. See FIG. 2. Suitable substrates were provided in conjunction with the description of step 106 of FIG. 1, above. Further, as described above, if the substrate material itself is not inherently conducting then the substrate is preferably coated with a conductive coating/layer. This situation is depicted in FIG. 2, wherein the substrate 202 has been coated with a layer 204 of conductive material. Suitable conductive materials for forming layer 204 include, but are not limited to, molybdenum (Mo), which may be coated on the substrate 202 using for example sputtering and evaporation.

Next, as illustrated in FIG. 3, a Cu₂ZnSn(Se,S)₄ kesterite film 302 is formed on the substrate 202. In the particular example shown in FIG. 3, the substrate 202 is coated with the conductive layer 204 and the kesterite film 302 is formed on the conductive layer 204. Kesterite layer 302 may be formed on the substrate 202 using the techniques described in conjunction with the description of methodology 100 of FIG. 1, above. The kesterite film 302 will serve as an absorber layer of the device.

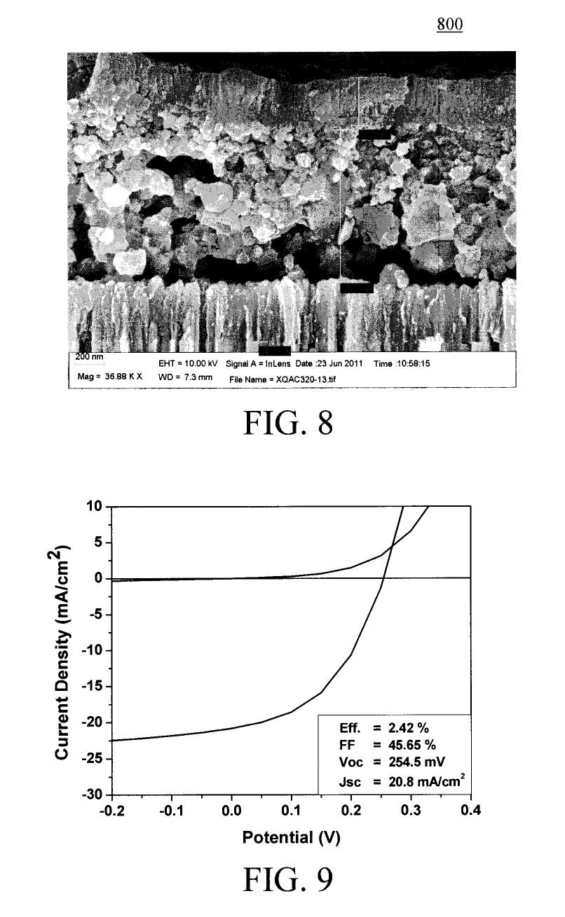

An n-type semiconducting layer 402 is then formed on the kesterite layer 302. According to an exemplary embodiment, the n-type semiconducting layer 402 is formed from zinc sulfide (ZnS), cadmium sulfide (CdS), indium sulfide (InS), oxides thereof and/or selenides thereof, which is deposited on the kesterite layer 302, using for example chemical bath deposition, chemical vapor deposition (CVD), thermal evaporation. or electrochemical deposition, to a thickness of from about 2 nm to about 80 nm. Next, a top electrode 404 is formed on the n-type semiconducting layer 402. As highlighted above, the substrate 202 (if inherently conducting) or the layer 204 of conductive material serves as a bottom electrode of the device. Top electrode 404 is formed from a transparent conductive material, such as doped zinc oxide (ZnO), indium-tin-oxide (ITO), doped tin oxide or carbon nanotubes. By way of example only, the top electrode is formed by depositing (e.g., sputtering) a ZnO layer that is from about 70 nm to about 80 nm thick and then depositing (e.g., sputtering) an ITO layer that is from about 110 nm to about 120 nm thick on the ZnO layer. Additionally, metal contacts containing, e.g., Ni and Al may be formed, as is known in the art, on the top electrode using, for example, electron beam evaporation. An image of an exemplary photovoltaic device produced using the present techniques is shown in FIG. 8, described below.

The present techniques are further described by way of reference to the following non-limiting examples.

### Examples of Preparing Chalcogen Containing Solution Using Ammonia Borane

### Example 1

In this example, a selenium/ethylene glycol solution is produced. 1.98 grams (g) of selenium powder, of formula Se, and 0.4 g of ammonia borane, of formula NH₃BH₃, are mixed with 4 mL of ethylene glycol, of formula (CH₂OH)₂ (5-6 M Se). The mixture is slowly heated to from about 80° C. to about 100° C. under vigorous stirring on a hot plate. A red solution is formed after releasing a large amount of gas (possibly H₂), as indicated by bubbling during the heat treatment. The color of the solution can become colorless, when the temperature ramps too fast. From about 200 microliters (μL) to about 500 μL of ammonia hydroxide, of formula NH₄OH, is useful to accelerate the dissolving process. However, for Se concentrations lower than 2 M, ammonia hydroxide is not necessarily needed to affect the dissolution.

### Example 2

In this example, a selenium/dimethyl sulfoxide (DMSO) solution is produced. 0.8 g of selenium powder, of formula Se, and 0.3 g of ammonia borane, NH₃BH₃, are added into 4 milliliters (mL) of DMSO of formula (CH₃)₂SO, under stirring. The mixture is slowly heated to around 80° C. on a hot plate. The black powders slowly dissolve into DMSO and the colorless solution becomes green. Slow bubbling is observed during the heat treatment. However, excess heating may cause uncontrollable bubbling and result in Se powders to precipitate. After all the powders are dissolved, the solution is cooled down to room temperature with continued stirring. From about 500 μL to about 1 mL of ammonia hydroxide may be needed to accelerate the dissolving process.

### Example 3

In this example a selenium/2-methoxyethanol solution is produced. 1.58 g of selenium powder, Se, and 0.3 g of ammonia borane, NH₃BH₃, are mixed with 4 mL of 2-methoxyethanol, of formula C₃H₈O₂, under stirring. The mixture is slowly heated up on a hot plate until the solution is bubbling. When large amount of out-gassing is happening (possibly H₂), the solution is immediately placed on another cold stir plate and stirred continuously until all the powders are dissolved. Then the solution is cooled down to room temperature. In this case, from about 100 μL to about 500 μL of ammonia hydroxide can help accelerate the dissolving process.

### Example 4

In this example, a selenium/acetone solution is produced. 1.58 g of selenium powder, Se, and 0.4 g of ammonia borane, NH₃BH₃, are added into 4 mL of acetone, of formula (CH₃)₂CO, under stirring. The mixture is gently heated on a hot plate under vigorous stirring. The black powders are slowly dissolved after 20 minutes. Outgassing is observed during the heat treatment (possibly H₂). Then the solution is placed on a cold plate and kept stirring until it cools down to room temperature. In this case, from about 200 μL to about 500 μL of ammonia hydroxide is helpful to the dissolving of Se powders.

### Example 5

In this example, a selenium/ammonia hydroxide (NH₄OH) solution is produced. 1.98 g of selenium powder, Se, and 0.325 g of ammonia borane, NH₃BH₃, are added into 4 mL of ammonia hydroxide of formula NH₄OH, under stirring. The mixture is slowly heated up on a hot plate until gaseous substance starts to generate (possibly H₂). The solution is then placed on a cold stir plate and kept stirring until it cools to room temperature. The cooled down solution is then filtered with a 1 μm filter to remove possible precipitated NH₄BO₂. The final solution is red and clear.

### Example 6

In this example, a sulfur/2-methoxyethanol solution is prepared. 0.5 g of sulfur powder, 0.2 g ammonia borane, 0.3 mL of NH₄OH are added into 3 mL of 2-methoxyethanol under vigorous stirring. The mixture is gently heated up to 100° C. on a hot plate under stirring. The yellow powders are slowly dissolved after 3 hours. There is some outgassing (possibly H₂) during the heat-treatment. The solution is placed on a cold stir plate and kept stirring until it cools to room temperature. The final solution is a red and clear solution.

### Example 7

In this example, a selenium/1-methylimidazole (1-MeIm) solution is prepared. 1.98 g selenium powder, Se, and 0.4 g of ammonium borane, NH₃BH₃, are added into 4 mL of 1-MeIm of formula CH₃C₃H₃N₂, under stirring. The mixture is slowly heated on a hot plate until gaseous substance (possibly H₂) starts to form. The solution is then placed on a cold stir plate and kept stirring until it cools to room temperature. The final solution is dark greenish in color. No ammonia hydroxide is needed in this example.

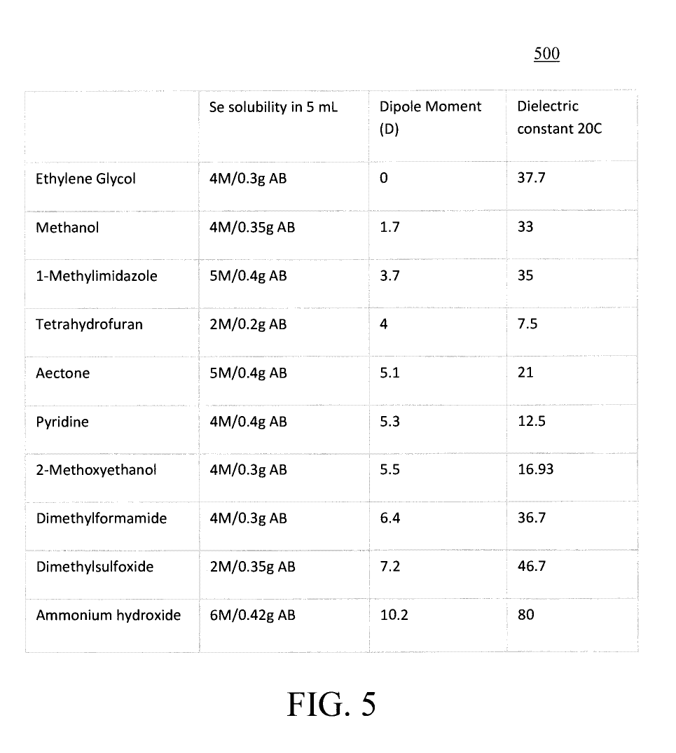

FIG. 5 is a table 500 that summarizes the results of solvents used for dissolving Se powder. In table 500, “AB” is an abbreviation for ammonia borane.

### Examples of Preparing Metal Chalcogenide Nanoparticles

### Example 8

The preparation can be carried out in a chemical hood, a nitrogen-filled glove box or a Schlenk line. In this example, the nanoparticles are all prepared in a chemical hood. The nanoparticles were synthesized by first dissolving 0.188 g zinc chloride of formula ZnCl₂, 0.341 g copper(II) chloride dihydrate of formula CuCl₂.2H₂O, and 0.308 g tin(IV) chloride pentahydrate of formula SnCl₄.5H2O, in 30 mL of deionized water under vigorous stirring. Then 3 mL of Se solution prepared by example 5 are slowly added into the above solution under vigorous stirring to form a black suspension. Then 2-6 mL of 40-48% wt ammonia sulfide of formula (NH₄)₂S were added under vigorous stirring to form a homogeneous black colloid. The nanoparticle suspension was stirred for 30 minutes, then separated from solution by centrifugation at speed of 3,600 rpm for 30 minutes, followed by washing with water and centrifuging at 3,600 rpm for 30 minutes for 2 times. Then a black precipitate of copper-, tin- and zinc-containing chalcogenide nanoparticle mixture was obtained.

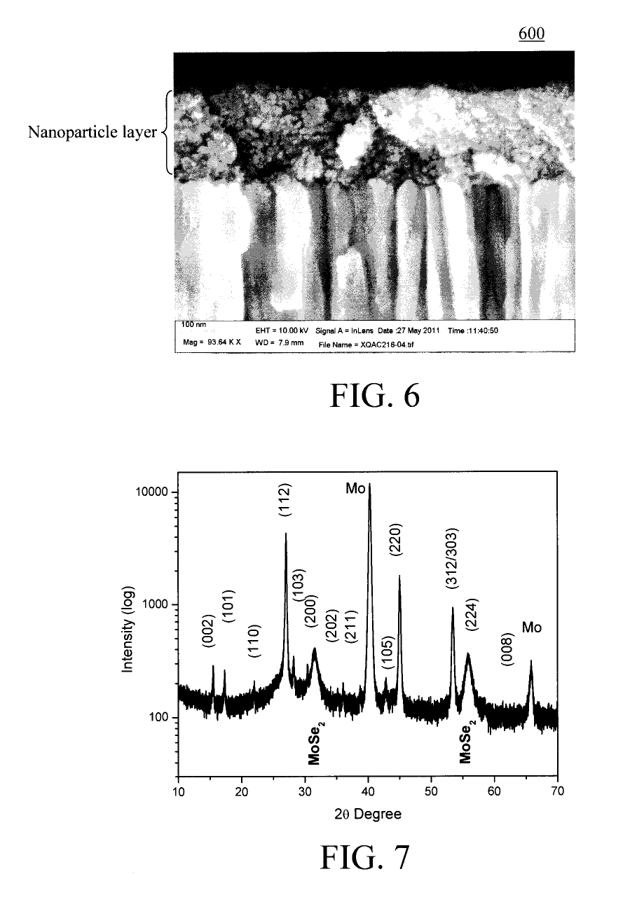

FIG. 6 is a scanning electron micrograph (SEM) image 600 of a layer of nanoparticles deposited on a Mo-coated substrate. The size of the nanoparticles are all below 20 nm.

### Example of Preparing Nanoparticles Based CZTSSe Ink

### Example 9

The preparation of a CZTSSe ink is carried out in a chemical hood. The centrifuged nanoparticles prepared by example 8 are suspended into 3 mL of deionized water in an ultrasonic bath and vigorously agitated using magnetic stirring to form 5 ml of colloid. Then 5 mL of Se-containing solution prepared by example 5 are slowly added under stirring to form 10 mL of black suspension. The suspension was continued to stir for from about 12 hours to about 24 hours before deposition. The obtained ink is stable for deposition for at least 2 weeks.

### Example of Preparation of Cu₂ZnSn(S,Se)₄ Film

### Example 10

Films were deposited on soda lime glass substrates coated with 700 nm of molybdenum by spin coating of the CZTSSe ink of example 9 at 800 rpm and heating at 450° C. for 2 minutes. The coating and heating cycle was repeated 6 times before a final anneal was carried out at 540° C. for 15 minutes. All of the coating and annealing processes were carried out in a nitrogen-filled drybox. FIG. 7 is a diagram illustrating the X-ray diffraction pattern of the obtained film. All the peaks can be indexed to the kesterite phase CZTSe (JCPDS 26-0575).

### Photovoltaic Devices Prepared by the Present Techniques

### Example 11

Solar cells were fabricated from the above-described Cu₂ZnSn(Se,S)₄ films by deposition of 60 nm CdS buffer layer by chemical bath deposition, 80 nm insulating ZnO and 120 nm ITO (indium-doped zinc oxide) by sputtering. In addition to the shown structure, the Ni/Al metal contacts were deposited by electron-beam evaporation. FIG. 8 is a cross-section SEM image 800 of the photovoltaic device prepared by this method. Photovoltaic performance was measured under an ASTM G173 global spectrum, yielding Power Conversion Efficiency=2.42%, Fill Factor=45.65%, Voc=254.5 mV, Jsc=20.8 mA/cm² with film prepared by example 10. See graph 900 in FIG. 9. In graph 900, voltage (measured in volts (V)) is plotted on the x-axis and current density (measured in milliamps per square centimeter (mA/cm²) is plotted on the y-axis. The current-voltage plots are given both under dark and light conditions.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method for preparing a chalcogen-containing solution, comprising the steps of:
contacting at least one chalcogen element, a reducing agent and a liquid medium under conditions sufficient to produce a homogenous solution, wherein the reducing agent (i) contains both boron and hydrogen, (ii) is substantially carbon free and (iii) is substantially metal free.

2. The method of claim 1, wherein the chalcogen element is selected from the group consisting of S, Se and Te.

3. The method of claim 1, wherein the reducing agent has a carbon content of less than about 2 atomic percent.

4. The method of claim 1, wherein the reducing agent has a metal content of less than about 100 ppm.

5. The method of claim 1, wherein the reducing agent contains at least one of the functional groups BH₃ and BH₄.

6. The method of claim 5, wherein the reducing agent is ammonia borane.

7. The method of claim 1, wherein the liquid medium comprises a solvent selected from the group consisting of water, ammonium hydroxide, ammonium hydroxide-water mixtures, alcohols, ethers, glycols, aldehydes, ketones, alkanes, amines, dimethylsulfoxide (DMSO), cyclic compounds and halogenated organic compounds.

8. The method of claim 1, wherein the conditions comprise a temperature of from about −50° C. to about 300° C.

9. The method of claim 1, wherein the conditions comprise a temperature of from about 15° C. to about 250° C.

10. A method for preparing a metal-chalcogenide ink, comprising the steps of:
preparing a chalcogen-containing solution according to the method of claim 1;
contacting at least one metal source with the chalcogen-containing solution under conditions sufficient to produce metal-chalcogenide nanoparticles;
isolating the metal-chalcogenide nanoparticles; and
dispersing the metal-chalcogenide nanoparticles in a liquid medium to form the metal-chalcogenide ink.

11. The method of claim 10, wherein the metal source is selected from the group consisting of: elemental Cu, elemental Zn, elemental Sn, elemental Ge, elemental In, elemental Fe, elemental Ga, Cu—Sn alloys, Cu—Zn alloys, Zn—Sn alloy, Cu—Al alloys, Cu—Ni alloys, Cu—In alloys, In—Ga alloys, copper chloride, copper bromide, copper fluoride, copper iodide, zinc chloride, zinc bromide, zinc fluoride, zinc iodide, tin chloride, tin bromide, tin iodide, indium chloride, germanium chloride, gallium chloride, indium fluoride, indium bromide, indium iodide, iron chloride, iron bromide, copper acetate, zinc acetate, tin acetate, iron acetate, indium acetate, copper nitrate, zinc nitrate, tin nitrate, iron nitrate, indium nitrate, copper sulfate, zinc sulfate, tin sulfate, iron sulphate, indium sulfate, CuS, Cu₂S, CuSe, Cu₂Se, Cu₂SnS₃, Cu₄SnS₄, Cu₂SnSe₃, CuInS₂, CuInSe₂, CuGaSe₂, Cu(In,Ga)Se₂, Cu(In,Ga)(S,Se)₂, SnS, SnS₂, SnSe, SnSe₂, ZnS, ZnSe, Cu₂ZnSnS₄, Cu₂ZnSnSe₄, Cu₂ZnSn(S,Se)₄, FeS, FeS₂, copper acetylacetonate, zinc acetylacetonate, tin(II) phthalocyanine and iron pentacarbonyl.

12. The method of claim 10, wherein the conditions comprise a temperature of from about 20° C. to about 300° C.

13. The method of claim 10, wherein the metal-chalcogenide nanoparticles are isolated using centrifugation or filtration.

14. The method of claim 10, wherein the liquid medium comprises a chalcogen-containing solution prepared according to the method of claim 1.

15. A method of preparing a kesterite film on a substrate, comprising the steps of:
preparing a chalcogen-containing solution according to the method of claim 1;
contacting at least one metal source with the chalcogen-containing solution under conditions sufficient to produce metal-chalcogenide nanoparticles containing Cu, Sn, Zn and at least one of S and Se;
isolating the metal-chalcogenide nanoparticles;
dispersing the metal-chalcogenide nanoparticles in a liquid medium to form an ink;
depositing the ink on the substrate to form a metal-chalcogenide precursor layer on the substrate; and
heat treating the metal-chalcogenide precursor layer to form the kesterite film on the substrate.

16. The method of claim 15, wherein the kesterite film has a formula Cu₂₋ₓZn_{1+y}Sn(S_{1-z}Se_{z})_{4+q}, wherein 0≦x≦1; 0≦y≦1; 0≦z≦1; −1≦q≦1.

17. The method of claim 16, wherein x, y, z and q respectively are: 0≦x≦0.5; 0≦y≦0.5; 0≦z≦1 and −0.5≦q≦0.5.

18. The method of claim 15, wherein the metal source comprises a Cu source, a Sn source and a Zn source.

19. The method of claim 15, wherein the metal source is selected from the group consisting of: elemental Cu, elemental Zn, elemental Sn, Cu—Zn alloys, Zn—Sn alloys, Cu—Sn alloys, copper chloride, copper fluoride, copper bromide, copper iodide, zinc bromide, zinc fluoride, zinc chloride, zinc iodide, tin chloride, tin bromide, tin iodide, copper acetate, zinc acetate, tin acetate, copper nitrate, zinc nitrate, tin nitrate, copper sulfate, zinc sulfate, tin sulfate, CuS, Cu₂S, CuSe, Cu₂Se, Cu₂SnS₃, Cu₄SnS₄, Cu₂SnSe₃, ZnS, ZnSe, SnS, SnS₂, SnSe, SnSe₂, Cu₂ZnSnS₄, Cu₂ZnSnSe₄, Cu₂ZnSn(S,Se)₄.

20. The method of claim 15, wherein the conditions comprise a temperature of from about 20° C. to about 300° C.

21. The method of claim 15, wherein the metal-chalcogenide nanoparticles are isolated using centrifugation or filtration.

22. The method of claim 15, wherein the liquid medium comprises a chalcogen-containing solution prepared according to the method of claim 1.

23. The method of claim 15, wherein the substrate is selected from the group consisting of: a metal foil substrate, a glass substrate, a ceramic substrate, aluminum foil coated with a layer of molybdenum and a polymer substrate.

24. The method of claim 15, wherein the ink is deposited on the substrate using spin-coating, dip-coating, doctor blading, curtain coating, slide coating, spraying, slit casting, meniscus coating, screen printing, ink jet printing, pad printing, flexographic printing or gravure printing.

25. The method of claim 15, wherein the metal-chalcogenide layer is heat treated at a temperature of from about 200° C. to about 800° C.

26. The method of claim 15, wherein the metal-chalcogenide layer is heat treated at a temperature of from about 400° C. to about 600° C.

27. A photovoltaic device, comprising:
a substrate;
a kesterite film absorber layer having a formula Cu₂₋ₓZn_{1+y}Sn(S_{1-z}Se_{z})_{4+q}, wherein 0≦x≦1; 0≦y≦1; 0≦z≦1; and −1≦q≦1 formed on the substrate by the method of claim 15;
an n-type semiconducting layer on the kesterite film; and
a top electrode on the n-type semiconducting layer.

28. The photovoltaic device of claim 27, further comprising:
an electrically conductive layer on the substrate.
